(19) United States
(12) Patent Application Publication
(10) Pub. No.: US 2021/0343964 A1
(43) Pub. Date: Nov. 4, 2021

(54) OLED DEVICE AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Xu CHEN, Wuhan, Hubei (CN)

(21) Appl. No.: 16/613,527

(22) PCT Filed: Sep. 19, 2019
(86) PCT No.: PCT/CN2019/106735

§ 371 Date: Nov. 14, 2019

(30) Foreign Application Priority Data
Jul. 9, 2019 (CN) 201910613656.3

(51) Int. Cl. H01L 51/50; H01L 51/52

(52) U.S. Cl. CPC H01L 51/502; H01L 51/5092; H01L 51/5056; H01L 2251/558; H01L 51/5036; H01L 51/5206; H01L 51/5221; H01L 51/5072

(57) ABSTRACT

An organic light emitting diode (OLED) device and a display device, the OLED device includes a substrate, an anode, a hole injection layer, a hole transport layer, a light emitting layer, an electron transport layer, an electron injection layer, and a cathode. Further, the light emitting layer includes a luminescent body material and a quantum dot material, and the luminescent body material includes a phosphorescent material for emitting green light and emitting red light, and a fluorescent material for emitting blue light.

### FIELD OF INVENTION

The present disclosure relates to the field of display technology, and particularly relates to an organic light emitting diode (OLED) device and a display device.

### BACKGROUND OF INVENTION

Present flat-panel display devices mainly include liquid crystal displays (LCDs) and organic light emitting displays (OLEDs). OLEDs have characteristics, such as self-illumination, do not require backlight, high contrast, thin thickness, wide viewing angles, fast response speed, can be used for flexible panels, wide temperature applying range, simple structures, and simple process, and are considered to be a next generation of flat-panel display emerging application technology.

An OLED device of prior art includes a substrate, a transparent anode disposed on the substrate, a hole injection layer disposed on the transparent anode, a hole transport layer disposed on the hole injection layer, a light emitting layer disposed on the hole transport layer, an electron transport layer disposed on the light emitting layer, an electron injection layer disposed on the electron transport layer, and a cathode disposed on the electron injection layer.

One technical problem is that green light and red light are emitted by adopting phosphorescence, which realizes a high quantum yield. However, the cost of phosphorescent dopant material is very high. Due to lifetime limitation of blue phosphorescent material, OLEDs of blue light are still doped by fluorescent materials. A half peak width of a photoluminescence spectroscopy (PL spectrum) of blue light doping material on current market is generally about 50 nm and has a significant shoulder peak, resulting in low top emission efficiency. Therefore, the prior art has yet to be improved and developed.

### SUMMARY OF INVENTION

An embodiment of the present disclosure provides an organic light emitting diode (OLED) device and display device, which has solved the problems that the high cost of phosphorescent organic material of red light and green light in OLED devices, and efficiency of the blue light fluorescent material is insufficient, and finally improves the luminous efficacy of the OLED devices.

In order to solve problems mentioned above, on first aspect, the present disclosure provides an organic light emitting diode (OLED) device, which includes a substrate, an anode, a hole injection layer, a hole transport layer, a light emitting layer, an electron transport layer, an electron injection layer, and a cathode; further, the light emitting layer includes a luminescent body material and a quantum dot material, and the luminescent body material includes a phosphorescent material for emitting green light and emitting red light, and a fluorescent material for emitting blue light.

Further, a half peak width of the quantum dot material ranges from 12 nm to 18 nm, and mass of the quantum dot material accounts for 1% to 50% of mass of the light emitting layer.

According to several embodiments of the present disclosure, colors of light emitted from the luminescent body material and the quantum dot material are same.

The present disclosure further provides an OLED device, which includes a substrate, an anode, a hole injection layer, a hole transport layer, a light emitting layer, an electron transport layer, an electron injection layer, and a cathode; further, the light emitting layer includes a luminescent body material and a quantum dot material, and the luminescent body material includes a phosphorescent material for emitting green light and emitting red light, and a fluorescent material for emitting blue light.

According to several embodiments of the present disclosure, colors of light emitted from the luminescent body material and the quantum dot material are same.

According to several embodiments of the present disclosure, an emission spectrum of the luminescent body material overlaps with an absorption spectrum of the quantum dot material.

According to several embodiments of the present disclosure, a half peak width of the quantum dot material ranges from 12 nm to 18 nm.

According to several embodiments of the present disclosure, mass of the quantum dot material accounts for 1% to 50% of mass of the light emitting layer.

According to several embodiments of the present disclosure, the quantum dot material includes at least one of organic-inorganic hybrid perovskite, inorganic perovskite quantum dots, 2-6 group quantum dots, 3-5 group quantum dots, 4-6 group quantum dots, or 1-3-6 group quantum dots, and core-shell structures of the 2-6 group quantum dots, core-shell structures of the 3-5 group quantum dots, core-shell structures of the 4-6 group quantum dots, or core-shell structures of the 1-3-6 group quantum dots.

According to several embodiments of the present disclosure, material of the hole injection layer, the hole transport layer, the electron transport layer, and the electron injection layer includes at least one of metal oxide nanoparticles, organic materials, or graphene.

According to several embodiments of the present disclosure, an energy level of material of the hole injection layer, the hole transport layer, the electron transport layer, and the electron injection layer matches an energy level of the quantum dot material.

According to several embodiments of the present disclosure, a thickness of the OLED device ranges from 50 nm to 1000 nm.

On second aspect, the present disclosure provides a display device, which includes an organic light emitting diode (OLED) device, and the OLED device includes a substrate, an anode, a hole injection layer, a hole transport layer, a light emitting layer, an electron transport layer, an electron injection layer, and a cathode; further, the light emitting layer includes a luminescent body material and a quantum dot material, and the luminescent body material comprises a phosphorescent material for emitting green light and emitting red light, and a fluorescent material for emitting blue light.

According to several embodiments of the present disclosure, colors of light emitted from the luminescent body material and the quantum dot material are same.

According to several embodiments of the present disclosure, an emission spectrum of the luminescent body material overlaps with an absorption spectrum of the quantum dot material.

According to several embodiments of the present disclosure, a half peak width of the quantum dot material ranges from 12 nm to 18 nm.

According to several embodiments of the present disclosure, mass of the quantum dot material accounts for 1% to 50% of mass of the light emitting layer.

According to several embodiments of the present disclosure, the quantum dot material includes at least one of organic-inorganic hybrid perovskite, inorganic perovskite quantum dots, 2-6 group quantum dots, 3-5 group quantum dots, 4-6 group quantum dots, or 1-3-6 group quantum dots, and core-shell structures of the 2-6 group quantum dots, core-shell structures of the 3-5 group quantum dots, core-shell structures of the 4-6 group quantum dot, or core-shell structures of the 1-3-6 group quantum dots.

According to several embodiments of the present disclosure, material of the hole injection layer, the hole transport layer, the electron transport layer, and the electron injection layer includes at least one of metal oxide nanoparticles, organic materials, or graphene.

According to several embodiments of the present disclosure, an energy level of material of the hole injection layer, the hole transport layer, the electron transport layer, and the electron injection layer matches an energy level of the quantum dot material.

According to several embodiments of the present disclosure, a thickness of the OLED device ranges from 50 nm to 1000 nm.

The embodiments of the present disclosure are by doping quantum dot material into the luminescent body material to act as the organic light emitting layer for constructing the OLED device. Because the quantum dot material has properties, such as high purity of photochromacity, high luminous efficacy, narrow spectral half-width, and relatively low cost, the problem of the OLED device that the cost of red and green phosphorescent organic materials is too high, and the efficiency of blue fluorescent materials is insufficient is solved. Because quantum dot materials have quantum size effect, adjusting the quantum dot size can adjust the photoluminescence (PL) spectral position and energy level position, and collocate with material of the hole injection layer, the hole transport layer, the electron transport layer, and the electron injection layer which the energy level is matched, can reduce the potential energy barrier, and is facilitated the excitons to inject, transmit, and recombine; and due to the narrow emission spectrum of the quantum dot, and the high quantum yield, luminous efficacy of the OLED device finally is improved.

### DESCRIPTION OF DRAWINGS

To more clearly illustrate the technical solutions of the embodiments of the present disclosure, the accompanying figures of the present disclosure will be described in brief. Obviously, the accompanying figures described below are only part of the embodiments of the present disclosure, from which figures those skilled in the art can derive further figures without making any inventive efforts.

FIG. 1 is an embodiment schematic diagram of an organic light emitting diode (OLED) device provided by an embodiment of the present disclosure.

FIG. 2 is a flowchart of an OLED device provided by an embodiment of the present disclosure.

### DETAILED DESCRIPTION OF PREFERRED EMBODIMENTS

The technical solutions in the embodiments of the present disclosure are clearly and completely described in the following with reference to the accompanying drawings in the embodiments of the present disclosure. Obviously, the described embodiments are only part of the embodiments of the present disclosure, but are not all embodiments of the present disclosure. All other embodiments obtained by those skilled in the art based on the embodiments of the present disclosure without creative efforts are within the scope of the present disclosure.

In the description of the present disclosure, it is to be understood that the orientation or positional relationship indicated by the terms “center”, “longitudinal”, “transverse”, “length”, “width” “thickness”, “upper”, “lower”, “front”, “rear”, “left”, “right”, “vertical”, “horizontal”, “top”, “bottom”, “inside”, “outside”, etc is based on the orientation or positional relationship shown in the accompanying figures, which is merely for the convenience for describing of the present disclosure and for the simplification of the description, and is not intended to indicate or imply that the indicated devices or elements have a specific orientation or is constructed and operated in a specific orientation. Therefore, it should not be understood as a limitation on the present disclosure. Moreover, the terms “first” and “second” are used for descriptive purposes only and are not to be understood as indicating or implying relative importance or implicitly indicating the number of the indicated technical characteristics. Therefore, the characteristics defined by “first” or “second” may include one or more of the described characteristics either explicitly or implicitly. In the description of the present disclosure, the meaning of “a plurality” is two or more unless clearly and specifically defined otherwise.

In the present disclosure, the term “exemplary” is used to mean “serving as an example, instance, or illustration.” Any embodiment described in this application as “exemplary” is not necessarily to be interpreted as preferred or advantageous over other embodiments. The following description is presented for enable any person skilled in the art to make and use the present disclosure. In the following description, details are listed for the purpose of explanation. It should be understood that one skilled in the art will recognize that the present disclosure can be practiced without the specific details. In other embodiments, well-known structures and procedures are not described in detail to avoid unnecessary details making the description of the present disclosure to become opacity. Therefore, the present disclosure is not intended to be limited to the embodiments shown, but is in accordance with the broad scope of the principles and characteristics disclosed by present disclosure.

Due to quantum dots having characteristics, such as excellent thermal stability, high quantum efficiency, narrow half-peak width, and high color gamut; quantum dots are considered to be another great material of display technology after liquid crystal displays (LCDs) and organic light emitting diodes (OLEDs). Quantum dot material has a quantum size effect. With change of particle size, a spectrum of a system can be realized to move. Finally, a visible light range can be fully adjusted, and even ultraviolet and near infrared can be realized, and the efficiency is high. Currently, all major companies have quantum dot products appearing on the market. Perovskite quantum dots are a hotspot material in recent years. The perovskite quantum dots have excellent electrical properties such as fast electron migration speed and great exciton binding energy, long diffusion distance, and have optical properties such as very high fluorescence quantum efficiency. In recent years, the perovskite quantum dots have been widely used in researches such as solar energy batteries, laser devices, LEDs, flat panel displays, and other aspects.

Based on this, embodiments of the present disclosure provide an OLED device and a display device. The details are described below respectively.

First, embodiments of the present disclosure provide an OLED device. The OLED device includes a substrate, an anode, a hole injection layer, a hole transport layer, a light emitting layer, an electron transport layer, an electron injection layer, and a cathode. Further, the light emitting layer includes a luminescent body material and a quantum dot material, and the luminescent body material includes a phosphorescent material for emitting green light and emitting red light, and a fluorescent material for emitting blue light.

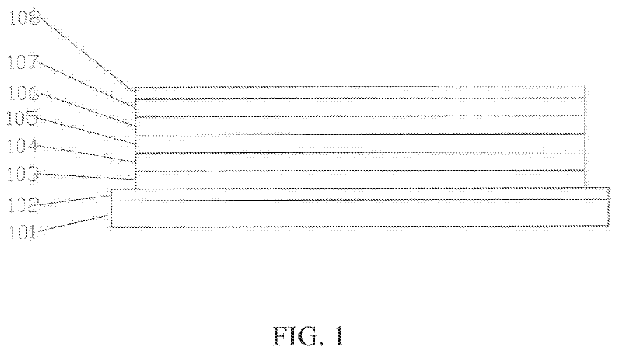

As illustrated in FIG. 1, it is an embodiment schematic diagram of an OLED device provided by an embodiment of the present disclosure. The OLED device includes a substrate 101, an anode 102, a hole injection layer 103, a hole transport layer 104, a light emitting layer 105, an electron transport layer 106, an electron injection layer 107, and a cathode 108. Further, in an embodiment of the present disclosure, through doping quantum dot material into the luminescent body material to act as the light emitting layer 105, and the luminescent body material includes a phosphorescent material for emitting green light and emitting red light, and a fluorescent material for emitting blue light.

Because the embodiments of the present disclosure are by doping quantum dot material into the luminescent body material to act as the light emitting layer 105 for constructing the OLED device. The quantum dot material has properties of high purity of photochromacity, high luminous efficacy, narrow spectral half-width, and relatively low cost, the problem of the OLED device that the cost of red and green phosphorescent organic materials is too high, and the efficiency of blue fluorescent materials is insufficient can be solved.

Based on the embodiments mentioned above, in another embodiment of the present disclosure, the substrate 101 can be a rigid substrate or a flexible substrate. The rigid substrate includes but is not limited to a glass substrate, a ceramics substrate, and a metal substrate; the flexible substrate is preferably polymer material, and includes but is not limited to polyimide and organic glass.

The anode 102 is preferably adopted indium tin oxide (ITO), which is covered on the substrate 101 by a vacuum sputtering process or an electroplating process. A thickness of the anode 102 preferably ranges from 5 nm to 500 nm, and more preferably ranges from 50 nm to 100 nm.

The cathode 108 is located on a light-exiting side of the OLED device, so a transparent electrode is required to be selected. Material of the cathode 108 includes but is not limited to one or more of aluminum, magnesium, zinc, iron, copper, or silver, and preferably is aluminum electrically conductive adhesive, silver electrically conductive adhesive, or magnesium electrically conductive adhesive, and can also be a silver electrically conductive thin film and an aluminum electrically conductive thin film. A thickness of the cathode 108 preferably ranges from 5 nm to 500 nm, and more preferably ranges from 50 nm to 200 nm.

Of course, in an embodiment of the present disclosure, the quantum dot material in the OLED device can also be further improved, and uniformity of size of the selected quantum dot material is good, which is beneficial to perform characteristics of the quantum dot material. Because the quantum dot material has quantum size effect, adjusting the quantum dot material size can adjust the photoluminescence spectral position and the energy level position of the quantum dot material. The quantum size effect refers to the phenomenon that the electron energy level near the metal Fermi level changes from quasi-continuous to discrete level, and the phenomenon that the nano-semiconductor particles have discontinuous energy levels of discontinuous maximum occupied molecular orbital and the lowest unoccupied molecular orbital and the energy gap widens, when the particle size drops to a certain value.

In an embodiment of the present disclosure, the OLED device is a monochromatic light structure, which does not require a filter. The colors of the light emitted from the luminescent body material and the quantum dot material are same through selection. Taking blue light as an example, the quantum dots are the quantum dots which emits blue light. The organic body material is correspondingly a blue organic body material, which mainly functions an energy transfer effect to transmit excitons to the doped quantum dots, and the quantum dots emit light. With the same reason, the red organic body material corresponds to quantum dots which emits red light, and the green organic body material corresponds to quantum dots which emits green light to solve the problems that the high cost of phosphorescent organic material of red light and green in OLED devices, and efficiency of the blue light fluorescent material is insufficient. When three materials of a red material, a green material and a blue material are evaporated together, a white light device is obtained. Further, making an emission spectrum of the luminescent body material overlap with an absorption spectrum of the quantum dot material to reduce non-absorption loss and heat loss of photons; a refractive index of each material on the light propagation path is matched to reduce total reflection critical angle loss and Fresnel loss, and a light trap is to reduce energy loss caused by leakage of light.

At the same time, it should be understood that through selecting the energy level of the material of the hole injection layer 103, the hole transport layer 104, the electron transport layer 106, and the electron transport layer 106 to match with the quantum dot material to reduce the potential barrier of the energy level of electron holes and electrons during injection and transmission, and is facilitated the excitons to inject, transmit, and recombine; and due to the narrow emission spectrum of the quantum dot, and the high quantum yield, luminous efficacy of the OLED device finally is improved.

The quantum dot material includes at least one of organic-inorganic hybrid perovskite, inorganic perovskite quantum dots, 2-6 group quantum dots, 3-5 group quantum dots, 4-6 group quantum dots, or 1-3-6 group quantum dots, and core-shell structures of the 2-6 group quantum dots, core-shell structures of the 3-5 group quantum dots, core-shell structures of the 4-6 group quantum dots, or core-shell structures of the 1-3-6 group quantum dots. For example, the organic-inorganic hybrid perovskite includes but is not limited to CH₃NH₃PbCl₃, CH₃NH₃PbBr₃, or CH₃NHaPbI₃; the inorganic perovskite quantum dot includes but is not limited to CsPbBr, CsPbCl, or CsPbI; the 2-6 group quantum dot includes but is not limited to a CdS quantum dot, a CdSe quantum dot, a CdTe quantum dot, a ZnS quantum dot, a ZnSe quantum dot, and a ZnTe quantum dot; the 3-5 group quantum dot includes but is not limited to a InAs quantum dot, a InP quantum dot, and a GaP quantum dot; the 1-3-6 group quantum dot includes but is not limited to a CuInS quantum dot, and a CuGaS quantum dot; the core-shell structure of the 2-6 group quantum dot includes but is not limited to a core-shell structure of a CdS quantum dot, a core-shell structure of a CdSe quantum dot, a core-shell structure of a CdTe quantum dot, a core-shell structure of a ZnS quantum dot, a core-shell structure of a ZnSe quantum dot, and a core-shell structure of a ZnTe quantum dot; the core-shell structure of the 3-5 group quantum dot includes but is not limited to a core-shell structure of a InAs quantum dot, a core-shell structure of a InP quantum dot, and a core-shell structure of a GaP quantum dot; and the core-shell structure of the 1-3-6 group quantum dot includes but is not limited to a core-shell structure of a CuInS quantum dot, and a core-shell structure of a CuGaS quantum dot.

Material of the hole injection layer 103, the hole transport layer 104, the electron transport layer 106, the electron injection layer 107 includes but is not limited to at least one of metal oxide nanoparticles, organic materials, or graphene, and preferably is ZnO; ZnMgO, 8-quinoline aluminum, 4,7-biphenyl-1, 10-phenanthroline (BPhen). The material of the hole injection layer 103 and the hole transport layer 104 can be same or be different. The material of the electron injection layer 106 and the electron transport layer 107 can be same or be different, and will not strictly limit herein, which is based on actual production requirements. The materials mentioned above are excellently combined with the material the light emitting layer 105, so that the luminous efficacy of the OLED device is remarkably improved.

On the basis of the embodiments mentioned above, in another embodiment of the present disclosure, specifically, a half peak width of the quantum dot material ranges from 12 nm to 30 nm, and preferably ranges from 12 nm to 18 nm, Due to the selected quantum dot material having narrow half peak width, high quantum efficiency; the monochromaticity of the emitted light is great, and is not affected by environment factors (temperature, voltage, etc.), after a top-emitting device is made, the energy utilization ratio is high.

In the light emitting layer 105, mass of the quantum dot material accounts for 1% to 50% of mass of the light emitting layer, and the doping ratio can be adjusted according to specific conditions, preferably ranges from 10% to 20%, and most preferably ranges from 12% to 15%.

In several embodiments of the present disclosure, a thickness of the OLED device ranges from 50 nm to 1000 nm, preferably ranges from 100 nm to 500 nm, and more preferably ranges from 100 nm to 200 nm.

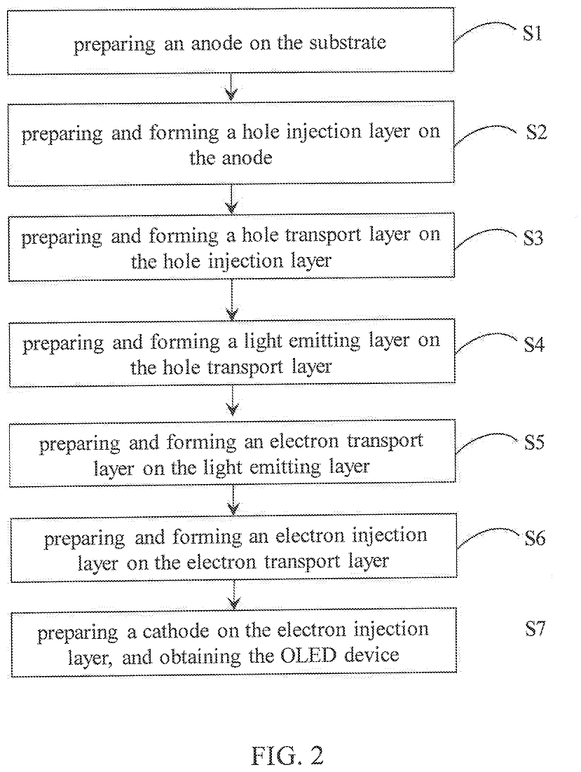

Based on the embodiments mentioned above, the present disclosure further provides a preparation method for an OLED display panel. As illustrated in FIG. 2, it is a flowchart of an OLED device provided by an embodiment of the present disclosure, which includes the following steps:

S1, preparing an anode on the substrate.

S2, preparing and forming a hole injection layer on the anode.

S3, preparing and forming a hole transport layer on the hole injection layer.

S4, dissolving luminescent body material and quantum dot luminescent material in an organic solution, and spin coating the mixed solution on the hole transport layer, after drying, obtaining a light emitting layer.

Specifically, preparation methods of the light emitting layer includes but is not limited to methods such as a vacuum evaporation method, an ink-jet printing method, a blade coating method, a spin-coating method, and a screen printing method.

S5, preparing and forming an electron transport layer on the light emitting layer.

S6, preparing and forming an electron injection layer on the electron transport layer.

S7, preparing a cathode on the electron injection layer, and obtaining the OLED device.

Referring to prior art, can prepare current layer structures such as the anode, the hole injection layer, the hole transport layer, the electron transport layer, the electron injection layer, and the cathode, and will not give unnecessary details herein.

In order to better achieve the purpose of the present disclosure, based on the basis of the OLED device mentioned above, a display device is further provided in the embodiment of the present disclosure. Through applying the OLED device described by the embodiments mentioned above, the luminous efficacy of the display device is further increased.

The specific principle of the display device of the present disclosure is same or similar to the description in the preferred embodiment of the OLED display panel mentioned above, for specific details, please refer to the related description in the preferred embodiment of the liquid crystal display panel mentioned above, and will not give unnecessary details herein.

It should be noted that, the structures is only described in the embodiments of the display panels mentioned above. It can be understood that, in addition to the structures mentioned above, the display device of the embodiments of the present disclosure may further include any other necessary structures as needed, and specifically, is not limited herein.

In the embodiments mentioned above, the descriptions to the various embodiments are emphasized, and the part is not described in detailed in an embodiment, can refer to the detailed description of other embodiments mentioned above, and will not give unnecessary details herein.

During a specific implementation, the various units or structures mentioned above may be implemented as a separate entity, or may be implemented in any combination, as the same or several entities. For the specific implementation of the various units or structures mentioned above, can refer to the method embodiments mentioned above, and will not give unnecessary details herein.

For the specific implementation of each operation can refer to the embodiments mentioned above, and will not give unnecessary details herein.

The OLED device provided by the embodiments of the present disclosure is described in detail. This article uses specific cases for describing the principles and the embodiments of the present disclosure, and the description of the embodiments mentioned above is only for helping to understand the method and the core idea of the present disclosure. Meanwhile, for those skilled in the art, will have various changes in specific embodiments and application scopes according to the idea of the present disclosure. In summary, the content of the specification should not be understood as limit to the present disclosure.

What is claimed is:

1. An organic light emitting diode (OLED) device comprising: a substrate, an anode, a hole injection layer, a hole transport layer, a light emitting layer, an electron transport layer, an electron injection layer, and a cathode;
wherein the light emitting layer comprises a luminescent body material and a quantum dot material, and the luminescent body material comprises a phosphorescent material for emitting green light and emitting red light, and a fluorescent material for emitting blue light;
a half peak width of the quantum dot material ranges from 12 nm to 18 nm, and mass of the quantum dot material accounts for 1% to 50% of mass of the light emitting layer.

2. The OLED device as claimed in claim 1, wherein colors of light emitted from the luminescent body material and the quantum dot material are same.

3. An organic light emitting diode (OLED) device comprising: a substrate, an anode, a hole injection layer, a hole transport layer, a light emitting layer, an electron transport layer, an electron injection layer, and a cathode;
wherein the light emitting layer comprises a luminescent body material and a quantum dot material, and the luminescent body material comprises a phosphorescent material for emitting green light and emitting red light, and a fluorescent material for emitting blue light.

4. The OLED device as claimed in claim 3, wherein colors of light emitted from the luminescent body material and the quantum dot material are same.

5. The OLED device as claimed in claim 4, wherein an emission spectrum of the luminescent body material overlaps with an absorption spectrum of the quantum dot material.

6. The OLED device as claimed in claim 3, wherein a half peak width of the quantum dot material ranges from 12 nm to 18 nm.

7. The OLED device as claimed in claim 3, wherein mass of the quantum dot material accounts for 1% to 50% of mass of the light emitting layer.

8. The OLED device as claimed in claim 3, wherein the quantum dot material comprises at least one of organic-inorganic hybrid perovskites, inorganic perovskite quantum dots, 2-6 group quantum dots, 3-5 group quantum dots, 4-6 group quantum dots, or 1-3-6 group quantum dots, and core-shell structures of the 2-6 group quantum dots, core-shell structures of the 3-5 group quantum dots, core-shell structures of the 4-6 group quantum dots, or core-shell structures of the 1-3-6 group quantum dots.

9. The OLED device as claimed in claim 3, wherein material of the hole injection layer, the hole transport layer, the electron transport layer, and the electron injection layer comprises at least one of metal oxide nanoparticles, organic materials, or graphene.

10. The OLED device as claimed in claim 3, wherein an energy level of material of the hole injection layer, the hole transport layer, the electron transport layer, and the electron injection layer matches an energy level of the quantum dot material.

11. The OLED device as claimed in claim 3, wherein a thickness of the OLED device ranges from 50 nm to 1000 nm.

12. A display device comprising: an organic light emitting diode (OLED) device, and the OLED device comprises a substrate, an anode, a hole injection layer, a hole transport layer, a light emitting layer, an electron transport layer, an electron injection layer, and a cathode;
wherein the light emitting layer comprises a luminescent body material and a quantum dot material, and the luminescent body material comprises a phosphorescent material for emitting green light and emitting red light, and a fluorescent material for emitting blue light.

13. The display device as claimed in claim 12, wherein colors of light emitted from the luminescent body material and the quantum dot material are same.

14. The display device as claimed in claim 13, wherein an emission spectrum of the luminescent body material overlaps with an absorption spectrum of the quantum dot material.

15. The display device as claimed in claim 12, wherein a half peak width of the quantum dot material ranges from 12 nm to 18 nm.

16. The display device as claimed in claim 12, wherein mass of the quantum dot material accounts for 1% to 50% of mass of the light emitting layer.

17. The display device as claimed in claim 12, wherein the quantum dot material comprises at least one of organic-inorganic hybrid perovskites, inorganic perovskite quantum dots, 2-6 group quantum dots, 3-5 group quantum dots, 4-6 group quantum dots, or 1-3-6 group quantum dots, and core-shell structures of the 2-6 group quantum dots, core-shell structures of the 3-5 group quantum dots, core-shell structures of the 4-6 group quantum dots, or core-shell structures of the 1-3-6 group quantum dots.

18. The display device as claimed in claim 12, wherein material of the hole injection layer, the hole transport layer, the electron transport layer, and the electron injection layer comprises at least one of metal oxide nanoparticles, organic materials, or graphene.

19. The display device as claimed in claim 12, wherein an energy level of material of the hole injection layer, the hole transport layer, the electron transport layer, and the electron injection layer matches an energy level of the quantum dot material.

20. The display device as claimed in claim 12, wherein a thickness of the OLED device ranges from 50 nm to 1000 nm.
